(19) United States
(12) Patent Application Publication
(10) Pub. No.: US 2006/0046515 A1
(43) Pub. Date: Mar. 2, 2006

(54) Micelle-containing composition, thin film thereof, and method for producing the thin film

(75) Inventors: Tomoko Maruyama, Kanagawa-ken (JP); Ken Equchi, Kanagawa-ken (JP); Koichi Sato, Kanagawa-ken (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 10/535,210

(22) PCT Filed: Dec. 25, 2003
(86) PCT No.: PCT/JP03/16704

§ 371 Date: May 17, 2005

(30) Foreign Application Priority Data
Jan. 10, 2003 (JP) 2003-003957

(51) Int. Cl. H01L 21/31

(52) U.S. Cl. 438/778

(57) ABSTRACT

The present invention provides a composition containing micelles that is useful as an optical material, and a method for producing a thin film using the same. The micelle-containing composition comprises at least micelles of an amphipathic block polymer, a polymer precursor and a dispersion medium therefor, the micelles containing a functional material. The method for producing a thin film comprises the steps of forming on a substrate a layer of the above composition and curing the composition.

### TECHINICAL FIELD

The present invention relates to a micelle-containing composition, a thin film thereof, and a method for producing the thin film. Particularly, it relates to a micelle-containing composition, a thin film thereof, and a method for producing the thin film where the composition and film thereof are useful as an optical material to be used for optical lenses such as the finder lens of a camera, optics such as a diffraction grating or multilayer film filter, and as a surface protective material for displays of computers or televisions to prevent reflection.

### BACKGROUND ART

In recent years, with daily use of liquid crystal displays, antireflective layers that would not impair brightness of the display have been required. For optics such as finder lens for a camera, a diffraction grating and multilayer film filter, materials having good workability and a desired refractive index have been required. Although resin processing technology represented by mold processing has been significantly developing in recent years, it is still difficult to realize films of sufficient refractive index using resin materials in comparison with conventional highly refractive inorganic oxide thin films formed using a conventional vacuum film-forming apparatus.

One of the most representative techniques is a method of mixing inorganic oxide fine particles of a high refractive index into a binder such as resin and curing it by heat. Recently, with the development of nano material technology, it has become possible to produce very fine particles (several tens to several hundreds nanometers) of an inorganic oxide with a high refractive index. However, it is still difficult to obtain a uniform thin film of high refractive index in which such fine particles are uniformly dispersed without agglomeration in a binder resin.

### DISCLOSURE OF THE INVENTION

The present invention was made to solve the above-described problems of the prior arts.

An aspect of the present invention relates to a micelle-containing composition that comprises at least micelles of an amphipathic block polymer containing a functional material, a polymer precursor and a dispersion medium therefor.

Moreover, a second aspect of the present invention relates to a thin film being a cured product of the above-described micelle-containing composition.

Furthermore, a third aspect of the present invention relates to a method for producing a thin film that comprises the steps of forming on a substrate a layer of the above-described composition and curing the above composition.

According to the present invention, there can be provided a composition containing micelles or reverse micelles showing high uniformity and dispersibility, and particularly, a composition containing reverse micelles containing a functional material.

Moreover, the present invention provides a reverse micelle-containing composition further containing a polymer precursor, so that a functional thin film can be provided in which a desired functional material is uniformly dispersed.

Furthermore, using an inorganic oxide fine particle as a functional material, a uniform thin optical film of a high refractive index can be provided easily.

### BEST MODE FOR CARRYING OUT THE INVENTION

The preferred embodiment of the present invention will be described in detail below.

The first aspect of the present invention is a micelle-containing composition that comprises at least micelles of an amphipathic block polymer containing a functional material, a polymer precursor and a dispersion medium therefor.

Moreover, the micelles contained in the composition of the present invention are reverse micelles. As a dispersion medium of the composition of the present invention, a liquid medium is particularly preferable. Preferably usable are water, a water-soluble solvent, a water-insoluble solvent, a resin and others. When a polymer precursor is a liquid, the polymer precursor itself may be used as a dispersion medium.

Preferably, the composition of the present invention is a composition containing a water-insoluble solvent as a dispersion medium. Examples of an available water-insoluble solvent are organic solvents and resins. Examples of such an organic solvent are hydrocarbon solvents such as hexane, heptane, octane, decane, toluene or isoper, and other solvents such as cyclohexanone, acetone, methylethylketone or butyl acetate. In addition, natural oil such as olive oil, soybean oil, beef tallow or lard may also be used. Moreover, silicone oil and fluorine oil may also be used. Examples of such a binder resin are a styrene acrylic copolymer and polyester.

The content of a dispersion medium used for the composition of the present invention is between 1% by weight and 99.8% by weight. It is preferably between 5% by weight and 99.5% by weight. It is more preferably between 10% by weight and 99% by weight. If the dispersion medium content is less than 1% by weight, dispersion of micelles may not be sufficient. In contrast, if it exceeds 99.8% by weight, the composition may not sufficiently function.

An amphipathic block polymer that is a component characteristically used in the present invention will be described below.

Specific examples of a block polymer that can be used in the present invention are conventional block polymers such as acryl or methacrylic block polymers, block polymers of polystyrene and other addition or condensation polymers, or block polymers having a polyoxyethylene or polyoxyalkylene block. In the present invention, a block polymer containing a polyvinyl ether structure is preferably used. Moreover, in the present invention, a block polymer may be a graft polymer having a polyvinyl ether structure, or a block polymer of which certain segment is such a copolymer segment. The style of copolymerization is not limited. It may be either a random segment or graduation segment, for example.

A block polymer having a polyvinyl ether structure that is preferably used in the present invention will be described below. Methods for synthesizing a polymer having a polyvinyl ether structure have been reported. A representative method is cationic living polymerization reported by Aoshima et al. (Japanese Patent Laid-Open Nos. H11-322942 and H11-322866). Such cationic living polymerization enables synthesis of various polymers such as homopolymer, copolymer of two or more kinds of monomers, block polymer, graft polymer or graduation polymer with precise control of the length (molecular weight). In addition, various functional groups can be introduced into the side chain of polyvinyl ether. Cationic polymerization can also be carried out using an HI/I₂ system, an HCl/SnCl₄ system or the like.

Moreover, the structure of a block polymer having a polyvinyl ether structure may be a copolymer consisting of polyvinyl ether and other polymers. Otherwise, it may also be a graft polymer obtained by grafting a block polymer to a macromolecular chain. The block polymer of the present invention may preferably have a block form such as AB, ABA, ABD or ABDE. A, B, D and E represent block segments that are different from one another. Each block segment may be either a segment consisting of a single monomer unit, or copolymerized segment consisting of multiple repeating unit.

More specifically, the above described block polymer having a polyvinyl ether structure preferably has a repeating unit structure of polyvinyl ether. As a specific example, a unit structure represented by the following general formula (1) is preferable: 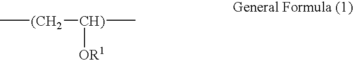
wherein R¹ represents one selected from the group consisting of a linear, branched or cyclic alkyl group having 1 to 18 carbon atoms, -Ph, -Pyr, -Ph-Ph, -Ph-Pyr, —(CH(R⁵)—CH(R⁶)—O)ₚ—R⁷ and —(CH₂)ₘ—(O)ₙ—R⁷, a hydrogen atom in the aromatic ring may be replaced with a linear or branched alkyl group having 1 to 4 carbon atoms, and a carbon atom in the aromatic ring may be replaced with a nitrogen atom, wherein p represents an integer of 1 to 18, m represents an integer of 1 to 36, n represents 0 or 1, each of R⁵ and R⁶ independently represents —H or —CH₃, R⁷ represents one selected from the group consisting of —H, a linear, branched or cyclic alkyl group having 1 to 18 carbon atoms, -Ph, -Pyr, -Ph-Ph, -Ph-Pyr, —CHO, —CH₂CHO, —CO—CH═CH₂, —CO—C(CH₃)═CH₂ and —CH₂COOR⁸, wherein if R⁷ is not a hydrogen atom, a hydrogen atom binding to a carbon atom in R⁷ may be replaced with a linear or branched alkyl group having 1 to 4 carbon atoms, —F, —Cl or —Br, and a carbon atom in the aromatic ring may be replaced with a nitrogen atom, R⁸ represents —H or an alkyl group having 1 to 5 carbon atoms, Ph represents a phenyl group, and Pyr represents a pyridyl group, -Ph-Ph represents a biphenyl group, and -Ph-Pyr represents a pyridylphenyl group. Each of these pyridyl group, biphenyl group and pyridylphenyl group may be any of possible positional isomers.

In the present invention, an amphipathic block polymer is used. Such an amphipathic block polymer can be obtained, for example, by selecting a hydrophobic block segment and a hydrophilic block segment from the repeating unit structure represented by the above general formula (1) and then synthesizing them.

Next, examples of the repeating unit structure of polyvinyl ether of a block polymer represented by the above general formula (1) will be given below. However, the polyvinyl ether structure used in the present invention is not limited thereto.

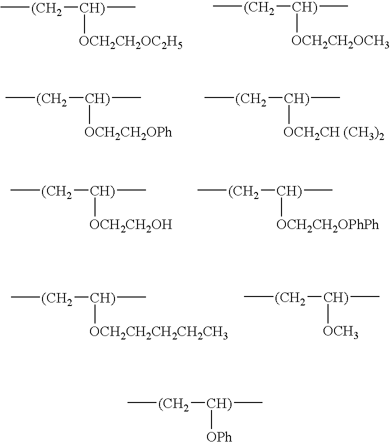

Other preferred examples of the above described block polymer having a polyvinyl ether structure of the present invention are made of a unit structure represented by the following general formula (2): 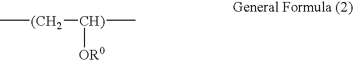
wherein R⁰ represents one selected from the group consisting of —X—COOH, —X—COOR¹⁰ and —X—COO-M, wherein X represents a linear, branched or cyclic alkylene group having 1 to 20 carbon atoms, or structure in which at least one selected from the group consisting of —(CH(R²)—CH(R³)—O)ₚ—(CH₂)ₘ—, —(CH₂)ₘ—(O)ₙ—(CH₂)_{q}— and a methylene group thereof may be substituted with a carbonyl group or aromatic ring structure, wherein p represents an integer of 1 to 18, m represents an integer of 1 to 36, n represents 1 or 0, q represents an integer of 1 to 18, R¹⁰ represents an alkyl group, M represents a monovalent or polyvalent cation, and each of R² and R³ represents an alkyl group, wherein R² and R³ may be identical to or different from each other.

Next, examples of the repeating unit structure of polyvinyl ether of the block polymer represented by the above general formula (2) are given below. However, a polyvinyl ether structure used in the present invention is not limited thereto.

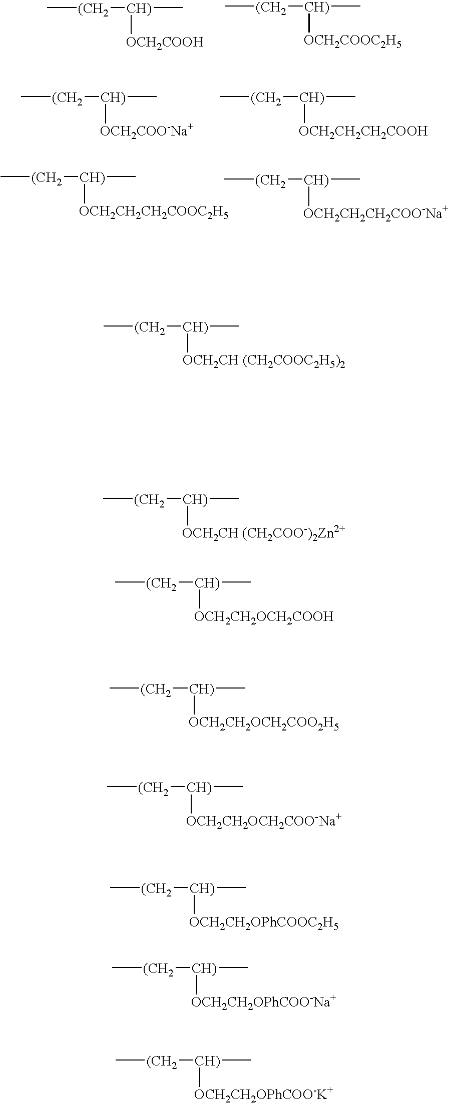

Several examples of polyvinyl ether block polymer structures containing these vinyl ether monomers will be given below. However, a polymer used in the present invention is not limited thereto.

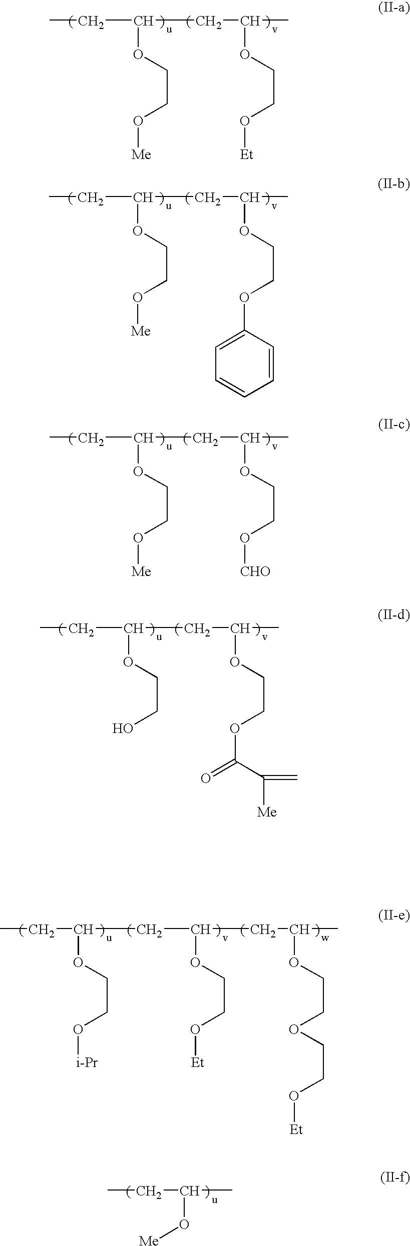

In the above polyvinyl ether structures, each of u, v and w representing repeating unit numbers is preferably between 3 and 10,000, and more preferably, the total (u+v+w) is between 10 and 20,000.

The molecular weight distribution=Mw (weight average molecular weight)/Mn (number-average molecular weight) of the block polymer used in the present invention is 2.0 or less, preferably 1.6 or less, more preferably 1.3 or less, and particularly preferably 1.4 or less. The number-average molecular weight (Mn) of the block polymer used in the present invention is preferably between 1,000 and 1,000,000. If Mn is less than 1,000 or exceeds 1,000,000, there may be some cases where a substance having certain functions cannot be well dispersed in a solvent.

It is desirable that the molecular motion of the block polymer is flexible in view of improvement of dispersion stability and inclusion property, because of the high physical affinity of the block polymer to a functional material; in view of easily formation of a coating layer on a substrate; and in view of formation of more uniform particles (micelles). Accordingly, the glass transition temperature Tg of the main chain of the block polymer is preferably 20° C. or lower, more preferably 0° C. or lower, and further more preferably −20° C. or lower. From these points also, a polymer having a polyvinyl ether structure, which has a low glass transition temperature and has flexible properties, is preferably used.

The content of the above block polymer in the composition of the present invention is between 0.1% and 80% by weight, and more preferably between 0.5% and 60% by weight. If the amount of the block polymer is less than 0.1% by weight, a functional material contained in the composition of the present invention may not be sufficiently dispersed or included in the micelle. If it exceeds 80% by weight, viscosity may become too large.

Moreover, in the present invention, the block polymer for the composition preferably has three or more block segments. A representative example is a triblock polymer. In this case, the polymer has at least one lyophilic segment, at least one lyophobic segment, and at least one block segment different from them. Since the triblock polymer has a lyophilic segment and a lyophobic segment that are necessary to form a reverse micelle particle and further has at least one segment having a different function, it can provide a highly functional dispersion composition.

Furthermore, the polymer precursor of the present invention preferably undergoes chemical change such as polymerization or crosslinking with stimulation such as heat, light etc. to be cured. For example, a monomer having an acrylate functional group is preferably used as an ultraviolet-curing monomer. Typical examples may include methyl methacrylate, alkyl methacrylate, alkylene dimethacrylate, methyl acrylate, alkyl acrylate, alkylene diacrylate, styrene, and styrene substituted products. Examples of a thermosetting resin that is preferably used may include a phenol resin, a polyester resin, and an epoxy resin.

When the above-described ultraviolet curing is carried out, a photopolymerization initiator may be added. Examples of such a photopolymerization initiator that is preferably used are acetophenones and benzophenones.

Still further, the composition of the present invention containing a functional material is preferably used in the formation of a thin film as described later. In particular, when a thin film of submicron order in thickness in which a desired functional material is uniformly dispersed is desired, the composition of the present invention is particularly preferably used. The functional material is preferably a liquid or solid, or it may be a soluble substance. In the present invention, especially, the composition is used as an optical material to form a thin film on the surface of a certain substrate.

The content of a functional material in the composition of the present invention is between 0.1% by weight and 99% by weight. It is preferably between 0.5% by weight and 90% by weight. It is more preferably between 0.5% by weight and 80% by weight. If the content of a functional material is less than 0.1% by weight, its function may not be sufficiently exhibited. A substance used to form a high refractive index layer is an example of a functional material that is preferably used for an optical material.

An inorganic oxide of a high refractive index in an ultra-fine particle form is preferably used as a functional material to form a high refractive index layer. Examples of such an inorganic oxide used to form a high refractive index layer may include ZnO (refractive index: 1.90), TiO₂ (refractive index: 2.3 to 2.7), CeO₂′ (refractive index: 1.95), Sb₂O₅ (refractive index: 1.71), SnO₂, ITO (refractive index: 1.95), Y₂O₃ (refractive index: 1.87), La₂O₃ (refractive index: 1.95), ZrO₂ (refractive index: 2.05), and Al₂O₃ (refractive index: 1.63).

In order to obtain a sufficient light transmittance without impairing the transparency of a high refractive index layer, the ultra-fine particles of inorganic oxide is preferably not larger than the wavelength of visible light, that is, a particle size thereof is preferably 200 nm or shorter, and more preferably 100 nm or shorter.

Next, the micelle particle of the present invention consisting of an amphipathic block polymer will be described.

In the present invention, an amphipathic block polymer used for micelle formation means a block polymer having both lyophilic and lyophobic properties. It is preferably a block polymer exhibiting both lyophilic and lyophobic properties to a medium containing a polymer precursor. This is typically a block polymer exhibiting both hydrophilic and hydrophobic properties. Micelle particles in an aqueous solvent have hydrophilic groups on the outer surface and hydrophobic groups at the core inside (ordinary micelle). On the contrary, micelle particles in an organic solvent have hydrophobic groups on the outer surface and hydrophilic groups at the core (reverse micelle).

In order to include a functional material in an amphipathic block polymer, first prepared are the amphipathic block polymer dissolved in either a hydrophilic solvent or hydrophobic solvent, and a desired functional material dissolved in either a hydrophilic solvent or hydrophobic solvent, and the following operation is carried out.

For example, a functional material dissolved or dispersed in an organic solvent is introduced into the hydrophobic core of micelles formed by a block polymer in water, and thereafter, the above organic solvent is removed, so as to include the above functional material into the block polymer.

For another example, a functional material dissolved or dispersed in an aqueous solution is introduced into the hydrophilic core of a micelle formed by a block polymer in an organic solvent, and thereafter, the above aqueous solution is removed, so as to include the above functional material into the block polymer.

In general, in industrial-scale thin film formation, an organic solvent system is preferable than an aqueous solvent system for the final composition containing a functional material and a film forming substance, in view of superior reproducibility in control of solution concentration, environmental conditions for film formation, etc.

When the above inorganic oxide fine particles are used as a functional material, the surface of the fine particles can be subjected to surface treatment, so that a solvent system in which the functional material is dispersed can be either an aqueous solvent or organic solvent (that is, a nonaqueous solvent).

A functional material is contained in the composition preferably at 90% or more by weight, more preferably 95% or more by weight, and most preferably 98% or more by weight based on the total weight of the composition.

Inclusion state the functional material can be confimed by instrumental analysis using various types of electron microscopes or X-ray diffractometry.

In the present invention, when micelles are formed with an amphipathic block polymer, a composition containing micelles of a mean particle size of 200 nm or shorter and a particle size distribution (dispersion index μ/G²) of 0.2 or less can be obtained.

Here, a mean particle size (diameter) is defined as the Stokes' diameter. Stokes' diameter can be measured by the sedimentation velocity method, the photon correlation method, the ultrasonic wave attenuation spectroscopy, etc. In the present invention, the particle size of a micelle or a reverse micelle in the present invention or that of a micelle or a reverse micelle containing a functional material is determined by the dynamic light scattering method. A dispersion index μ/G² (μ: the second coefficient of a cumulant expansion, G: attenuation coefficient) proposed by Gulari et al. is generally used as an index of uniformity of particle size (The Journal of Chemical Physics, vol. 70, p. 3965, 1979). This value is obtained also by the dynamic light scattering method. An example of particle size measuring instruments used in the above dynamic light scattering method is DLS 7000 manufactured by Otsuka Electronics Co., Ltd. A particle size measured with this instrument is defined as Stokes' diameter.

Since the composition of the present invention has a mean particle size of not more than 200 nm and such an extremely narrow particle size distribution (distribution index: μ/G²) as 0.2 or less, there is almost no interaction with visible light, and accordingly, it becomes possible to realize a substantially transparent state, regardless of the dispersion medium. More preferably, a mean particle size is 150 nm or shorter and a particle size distribution (distribution index: μ/G²) is 0.1 or less. Further more preferably, a mean particle size is 100 nm or shorter and a particle size distribution (distribution index: μ/G²) is 0.1 or less. If a mean particle size exceeds 200 nm and a particle size distribution (distribution index: μ/G²) exceeds 0.2, scattering of visible light may be conspicuous. Use of a block polymer having the aforementioned chemical structure described above in the composition is preferable because it enables realization of a small particle size and a uniform particle size distribution.

In the following, a process of forming a high refractive index thin film on a substrate such as a glass substrate using the above composition is described. The aforementioned composition, for example, a solution in which at least reverse micelle particles containing inorganic oxide fine particles therein and a photocurable polymer precursor are dispersed, is applied on a well-washed substrate by the spin coat method or the like, and cured by UV irradiation or heat treatment, so as to form a film.

The material of the substrate is not limited, and glass, metal or plastic can be used as a substrate. In addition, it is also possible to form an optical thin film with the composition of the invention on a glass substrate having a desired surface layer such as a metal thin film, metal oxide thin film or resin film. In this case, the application or curing method may be appropriately selected as described later, according to the substrate. For example, when a glass substrate or metal plate is used as a substrate, spin coating with high rotation numbers or heat curing can be used without difficulty. The optical thin film of the present invention can be formed easily on nonplanar substances such as a lens. Further, it is also applicable to products having fine unevenness on the surface.

As a method of applying the composition of the invention on the surface of a substrate or a desired structure, the spin coat method is preferably used for a substrate having parallel planes. However, the method is not limited thereto but it depends on a substrate's material, area, form, structure, surface state, or the thickness of a film of interest.

For example, a composition can be applied to a desired location by the drop method, dip method, laminate method, ink-jet method, etc., and then cured.

When a composition is cured by light irradiation, it is preferable that the composition of the present invention applied on a desired surface by the above-described method is subjected to an electromagnetic wave irradiation of which wave length is shorter than visible light. Electromagnetic waves having a wavelength shorter than that of visible light include γ ray, X ray and ultraviolet ray. From the viewpoint of practicability of equipment for applying such an electromagnetic wave to a substrate with a large area, ultraviolet ray is preferable. Examples of such ultraviolet ray source include an excimer lamp, a low-pressure mercury lamp, a high-pressure mercury lamp, and a metal halide lamp.

It is also preferable to improve the wettability of the substrate to form a uniform thin film, for example, by physical surface treatment such as a reverse sputtering technique, UV irradiation, or surface treatment with a silane coupling agent as appropriate.

Alternatively, in some cases, preheating using an oven etc. is preferably carried out after the application of the composition on the surface of a substrate, and then curing is carried out. In order to form a thin film of a certain film thickness on a substrate by the above described method, it is preferable to adjust the concentration of the above composition, the composition ratio of a block polymer, the size of a micelle formed by the block polymer, the size of a functional material contained in the micelle, especially in case of formation of a high refractive index thin film, the particle size of the inorganic oxide fine particles, the composition ratio when the inorganic oxide fine particles are dispersed in a solvent, etc. It is also preferable to control conditions for film formation such as rotation number in spin coating.

In the present invention, the thickness of a film to be formed is not particularly limited, but a thin film can be formed by controlling the component ratio of a composition or by adjusting the solvent.

The term “thin film” is used herein to mean “a material film of a thickness of one to several hundreds of molecules deposited on a solid substrate such as glass or ceramic or layered on a supporting liquid,” as defined in McGraw-Hill Dictionary of Scientific and Technical Terms.

The refractive index of an optical thin film that was formed can be measured using a refractometer. For example, a Pulfrich refractometer, Abbe refractometer or the like can be used. Alternatively, a method of measuring a reflectance and a transmittance and then obtaining a refractive index by curve fitting is also preferably used (e.g., “Hikari Device Jiten (Optical Device Dictionary)” The Optronics Co., Ltd., p. 48).

### EXAMPLE

The present invention will be specifically described below.

<Synthesis of Block Polymer>

Synthesis of a triblock polymer consisting of isobutyl vinyl ether (IBVE: block A), 2-methoxyethoxy vinyl ether (MOVE: block B) and 4-(2-vinyloxy)ethoxy ethyl benzoate (VEOEtPhCOOEt: block C)

A glass vessel equipped with a three-way cock was purged with nitrogen and heated to 250° C. under nitrogen gas atmosphere to remove adsorbed water. The system was cooled to room temperature, and 12 mmol (millimole) of IBVE, 16 mmol of ethyl acetate, 0.05 mmol of 1-isobutoxy ethyl acetate, and 11 ml of toluene were added thereto, followed by cooling the reaction system. When the temperature in the system reached 0° C., 0.2 mmol of ethylaluminum sesquichloride (an equimolar mixture of diethylaluminum chloride and ethylaluminum dichloride) was added thereto, so as to initiate polymerization. The molecular weight was monitored with time by gel permeation chromatography (GPC), so as to confirm completion of polymerization of block A.

Subsequently, 12 mmol of block B (MOVE) was added thereto to continue polymerization. Completion of polymerization of block B was confirmed by GPC monitoring. Thereafter, a toluene solution containing 10 mmol of block C was added thereto to continue polymerization. After 20 hours, the polymerization reaction was terminated. The polymerization reaction was quenched by adding 0.3% by weight of an ammonia/methanol aqueous solution was added into the reaction system.

The reaction mixture was diluted with dichloromethane, and then the diluted solution was washed with 0.6 mol/l hydrochloric acid 3 times and then with distilled water 3 times. The obtained organic layer was concentrated and evaporated using an evaporator, and the obtained product was subjected to vacuum drying. The thus obtained product was repeatedly dialyzed to methanol in a semipermeable cellulose membrane, so as to remove monomers and to collect a triblock polymer of interest. The triblock polymer was identified by using NMR and GPC. As a result, Mn=46,300 and Mw/Mn=1.36. The polymerization ratio A:B:C=200:200:30.

Moreover, the obtained block polymer was subjected to hydrolysis in a mixed solution of dimethylformamide and sodium hydroxide, so that the side chain of block C component was hydrolyzed to give a triblock polymer sodium salt. The compound was identified by NMR and GPC.

This polymer was dispersed in chloroform, so as to obtain a transparent dispersed solution. The dispersed particles were measured on d (mean particle size: diameter) and dispersion index (μ/G²) using a dynamic light scattering device (DLS-7000 manufactured by Otsuka Electronics Co., Ltd.). As a result, d was 155 nm and dispersion index (μ/G²) was 0.18.

At the same time, 50 ml of a mixed solution of water and ethanol in which TiO₂ fine particles were dispersed was prepared. The TiO₂ fine particles were contained at 30% by weight based on the total weight of the mixed solution. The TiO₂ particles were those having d of 100 nm previously determined by using a dynamic light scattering device (DLS-7000 manufactured by Otsuka Electronics Co., Ltd.).

Methyl methacrylate and hexanediol diacrylate were mixed at a ratio of 1:1, and the obtained mixture was used as a polymer precursor.

To 50 ml of the above dispersion of block polymer in chloroform, 15 ml of the polymer precursor (methyl methacrylate:hexanediol diacrylate=1:1) was added, and the mixture was well stirred.

To this mixture, the above TiO₂ fine particle-containing solution (20 ml) was gradually added with furtner stirring. The obtained solution was left at rest for a while, and then the supernatant solution was transferred to another container using a syringe. A glass substrate washed with neutral detergent and then treated by UV irradiation was coated with the supernatant by spin coating. Thereafter, UV was applied thereto at 10 mW/cm² for 5 minutes. When the surface of the glass substrate was carefully observed by naked eyes and by a light microscope, to show that a thin film of a thickness of approximately 100 angstroms was formed on the entire surface. The substrate was transparent.

When the thin film obtained by the aforementioned method was observed using a scanning electron microscope (SEM), it was found that the TiO₂ particles were uniformly distributed in the plane with almost no secondary agglomeration of the particles.

1. A micelle-containing composition comprising at least a micelle of an amphipathic block polymer, a polymer precursor and a dispersion medium therefor, wherein the micelle contains a functional material therein.

2. The composition according to claim 1, wherein said micelle is a reverse micelle.

3. The composition according to claim 1, wherein the functional material is an inorganic oxide.

4. The composition according to claim 1, wherein the polymer precursor is a substance curable with light or heat.

5. The composition according to claim 1, wherein the block polymer comprises three or more block segments.

6. The composition according to claim 1, wherein the block polymer is a high polymer having a repeating unit structure of polyvinyl ether.

7. A thin film being a cured product of a micelle-containing composition, wherein the composition comprises at least a micelle of an amphipathic block polymer, a polymer precursor and a dispersion medium therefor, and the micelle contains a functional material.

8. The thin film according to claim 7, wherein the thin film is formed on a substrate.

9. A method for producing a thin film, the method comprising the steps of:
forming on a substrate a layer of a composition; and
curing the composition layer,
wherein the composition comprises at least a micelle of an amphipathic block polymer and a polymer precursor in a dispersion medium thereof, and said micelle contains a functional material.

10. The method according to claim 9, wherein the curing step is carried out using heat and light.
